(19) United States
(12) Patent Application Publication
(10) Pub. No.: US 2026/0301815 A1
(43) Pub. Date: Oct. 1, 2026

(54) APPARATUS AND METHOD FOR IMPROVING CONSISTENCY OF PERFORMANCE IN A MEMORY DEVICE

(71) Applicant: SK hynix Inc., Icheon-si (KR)

(72) Inventor: Byeong Su KANG, Icheon-si (KR)

(21) Appl. No.: 19/306,423

(22) Filed: Aug. 21, 2025

(30) Foreign Application Priority Data
Mar. 26, 2025 (KR) 10-2025-0038594

(51) Int. Cl. G11C 16/08; G11C 16/10; G11C 16/30

(52) U.S. Cl. CPC G11C 16/08; G11C 16/102; G11C 16/30

(57) ABSTRACT

A memory system includes a memory device and a controller. The memory device is configured to access a plurality of memory cells through at least one of a plurality of word lines. The controller is configured to collect information regarding operating performance of each of at least some word lines among the plurality of word lines in the memory device, to group the at least some word lines into a plurality of groups based on a reference associated with the information, and to assign a data input/output operation to one of the plurality of groups to perform the data input/output operation.

### CROSS-REFERENCE TO RELATED APPLICATION

This patent application claims the benefit of Korean Patent Application No. 10-2025-0038594 in the Korean Intellectual Property Office, filed on Mar. 26, 2025, the entirety of which is incorporated herein by reference.

### TECHNICAL FIELD

One or more embodiments of the present disclosure described herein relate to a memory device and a memory system, and more particularly, to an apparatus and a method for improving performance consistency of the memory device.

### BACKGROUND

A data processing system including a memory system or a data storage device has been developed to store more data in the data storage device, store data in the data storage device more quickly, and output data stored in the data storage device more quickly. The data storage device may include non-volatile memory cells and/or volatile memory cells for storing data. Changes may occur in an operating state, operating environment, or the like of the memory device included in the memory system. Due to such changes, differences may occur in terms of data input/output performance of the memory device.

### BRIEF DESCRIPTION OF THE DRAWINGS

The description herein makes reference to the accompanying drawings wherein like reference numerals refer to like parts throughout the figures.

FIG. 1 illustrates a first data processing device according to an embodiment of the present disclosure.

FIG. 2 illustrates a second data processing device according to an embodiment of the present disclosure.

FIG. 3 illustrates a memory device according to an embodiment of the present disclosure.

FIG. 4 illustrates a structure of a first cell array according to an embodiment of the present disclosure.

FIG. 5 illustrates a structure of a second cell array according to an embodiment of the present disclosure.

FIG. 6 illustrates a structure of a third cell array according to an embodiment of the present disclosure.

FIG. 7 illustrates an operation method of a memory system according to an embodiment of the present disclosure.

FIG. 8 illustrates a method for adjusting and changing an access order or sequence for word lines in a memory device according to an embodiment of the present disclosure.

FIG. 9 illustrates consistent performance results based on a method for adjusting and changing the access order or sequence for word lines according to an embodiment of the present disclosure.

### DETAILED DESCRIPTION

Various embodiments of the present disclosure are described below with reference to the accompanying drawings. Elements and features of this disclosure may be configured or arranged differently to form other embodiments, which may be variations of any of the disclosed embodiments.

In this disclosure, references to various features (e.g., elements, structures, modules, components, steps, operations, characteristics, etc.) included in “one embodiment,” “example embodiment,” “an embodiment,” “another embodiment,” “some embodiments,” “various embodiments,” “other embodiments,” “alternative embodiment,” and the like are intended to mean that any such features are included in one or more embodiments of the present disclosure, but may or may not necessarily be combined in the same embodiments.

In this disclosure, the terms “comprise,” “comprising,” “include,” and “including” are open-ended. As used in the appended claims, these terms specify the presence of the stated elements and do not preclude the presence or addition of one or more other elements. Furthermore, the terms in a claim do not foreclose the apparatus from including additional components, e.g., an interface unit, circuitry, etc.

In this disclosure, various units, circuits, or other components may be described or claimed as “configured to” perform a task or tasks. In such contexts, “configured to” is used to connote structure by indicating that the blocks/units/circuits/components include structure (e.g., circuitry) that performs one or more tasks during operation. As such, the block/unit/circuit/component can be said to be configured to perform the task even when the specified block/unit/circuit/component is not currently operational, e.g., is not turned on nor activated. Examples of block/unit/circuit/component used with the “configured to” language include hardware, for example, circuits, memory storing program instructions executable to implement the operation, etc. Additionally, “configured to” can include a generic structure (e.g., generic circuitry) that is manipulated by software and/or firmware (e.g., an FPGA or a general-purpose processor executing software) to operate in manner that is capable of performing the task(s) at issue. “Configured to” may also include adapting a manufacturing process (e.g., a semiconductor fabrication facility) to fabricate devices (e.g., integrated circuits) that are adapted to implement or perform one or more tasks.

As used in this disclosure, the term ‘circuitry’ or ‘logic’ refers to all of the following: (a) hardware-only circuit implementations (such as implementations in only analog and/or digital circuitry) and (b) combinations of circuits and software (and/or firmware), such as (as applicable): (i) to a combination of processor(s) or (ii) to portions of processor(s)/software (including digital signal processor(s)), software, and memory(ies) that work together to cause an apparatus, such as a mobile phone or server, to perform various functions and (c) circuits, such as a microprocessor(s) or a portion of a microprocessor(s), that require software or firmware for operation, even if the software or firmware is not physically present. This definition of ‘circuitry’ or ‘logic’ applies to all uses of this term in this application, including in any claims. As a further example, as used in this application, the term “circuitry” or “logic” also covers an implementation of merely a processor (or multiple processors) or portion of a processor and its (or their) accompanying software and/or firmware. The term “circuitry” or “logic” also covers, for example, and if applicable to a particular claim element, an integrated circuit for a storage device.

As used herein, the terms “first,” “second,” “third,” and so on are used as labels for nouns that they precede, and do not imply any type of ordering (e.g., spatial, temporal, logical, etc.). The terms “first” and “second” do not necessarily imply that the first value must be written before the second value. Further, although the terms may be used herein to identify various elements, these elements are not limited by these terms. These terms are used to distinguish one element from another element that otherwise have the same or similar names. For example, a first circuitry may be distinguished from a second circuitry.

Further, the term “based on” is used to describe one or more factors that affect a determination. This term does not foreclose additional factors that may affect a determination. That is, a determination may be solely based on those factors or based, at least in part, on those factors. Consider the phrase “determine A based on B.” While in this case, B is a factor that affects the determination of A, such a phrase does not foreclose the determination of A from also being based on C. In other instances, A may be determined based solely on B.

Herein, a data entry, an entry of data, an item of data, or a data item may be a sequence of bits. For example, the data entry may include the contents of a file, a portion of the file, a page in memory, an object in an object-oriented program, a digital message, a digital scanned image, a part of a video or audio signal, metadata or any other entity which can be represented by a sequence of bits. According to an embodiment, the data entry may include a discrete object. According to another embodiment, the data entry may include a unit of information processed or handled for a data input/output operation. According to another embodiment, the data entry may include a unit of information within a transmission packet between two different components.

Embodiments of the present disclosure can provide a memory device, a memory system including the memory device, a controller included in the memory system, or a data processing device including the memory system.

An embodiment of the present disclosure can provide an apparatus and a method capable of reducing or avoiding deviations in operational performance of a memory system or a memory device to improve or enhance the operation performance.

An embodiment of the present disclosure can provide an apparatus and a method capable of maintaining and improving performance efficiency or consistency of a memory device by reducing differences in operation performance that occur depending on an operation state or an operation environment of the memory device.

When the performance consistency of the memory device according to an embodiment of the present disclosure is maintained and improved, performance quality (e.g., QoS) of the memory device could be improved so that operation reliability of the memory device and the memory system can be improved.

A memory device and a memory system according to an embodiment of the present disclosure can reduce or avoid a decrease in the consistency of operational performance of the memory device and the memory system by adjusting and changing an access order or sequence for word lines to reduce the deviation of the operational performance of the memory device.

In an embodiment, a memory system can include a memory device configured to access a plurality of memory cells through at least one of a plurality of word lines; and a controller configured to collect information regarding operating performance of each of at least some word lines among the plurality of word lines in the memory device, to group the at least some word lines into a plurality of groups based on a reference associated with the information, and to assign a data input/output operation to one of the plurality of groups to perform the data input/output operation.

The reference can include a median value and an average value.

The information can include the amount of time during which the data input/output operation is completed when the operation is performed through a corresponding word line in the memory device based on a command, transmitted from the controller.

In the memory system, at least one group among the plurality of groups comprises two word lines that are not arranged sequentially.

The controller can be configured to: determine a number of assigned groups among the plurality of groups in response to at least one write command and write data input from an external device; and generate a map address that connects a logical address for the write data and a physical address of the assigned group.

The number of assigned groups can be determined based on a size of the write data.

In the memory system, each of the plurality of groups can include a same number of word lines.

The memory device can include a voltage supply circuit that is configured to, during a program operation, apply a program voltage to a selected word line among the plurality of word lines and to apply a pass voltage to an unselected word line.

In the memory system, a sum of time lengths of the data input/output operation performed through the plurality of word lines included in each of the plurality of groups is substantially the same for each group.

In another embodiment, a method of operating a memory system can include collecting information regarding operating performance of each of at least some word lines among a plurality of word lines in a memory device; grouping the at least some word lines into a plurality of groups based on a reference associated with the information, and assigning a data input/output operation to one of the plurality of groups to perform the data input/output operation.

The data input/output operation can include a write operation for storing write data, transmitted from an external device, in the memory device.

The reference can include one of a median value and an average value.

The information can include the length of time in which the data input/output operation performed through a corresponding word line in the memory device based on a command, transmitted from a controller, is completed.

In the method, at least one group among the plurality of groups can include two word lines that are not arranged sequentially.

The method can further include receiving at least one write command and write data from an external device; determining a number of assigned groups among the plurality of groups based on a size of the write data; and generating a map data that links a logical address for the write data and a physical address of the assigned groups.

In the method, each of the plurality of groups can include the same number of word lines.

In the method, a sum of time lengths of the data input/output operation performed through the plurality of word lines included in each of the plurality of groups is substantially the same for each group.

In another embodiment, a memory device can include a plurality of memory cells; a plurality of word lines for accessing the plurality of memory cells; and a row decoder configured to receive at least one write command and a plurality of physical addresses, transmitted from a memory controller, and to select a plurality of word lines among the plurality of word lines based on the plurality of physical addresses. At least some of the selected word lines are not sequential with other selected word lines.

The memory device can further include a control logic configured to transmit a completion notification for the at least one write command to the memory controller after write data is completely programmed through the selected word lines.

The memory device can further include a voltage supply circuit configured, during a program operation, to apply a program voltage to one of the selected word lines and to apply a pass voltage to the other word lines among the plurality of word lines.

An embodiment described herein can provide an apparatus and a method for improving a data input/output operation of a memory system or a data processing system. Embodiments will now be described with reference to the accompanying drawings, wherein like numbers reference like elements.

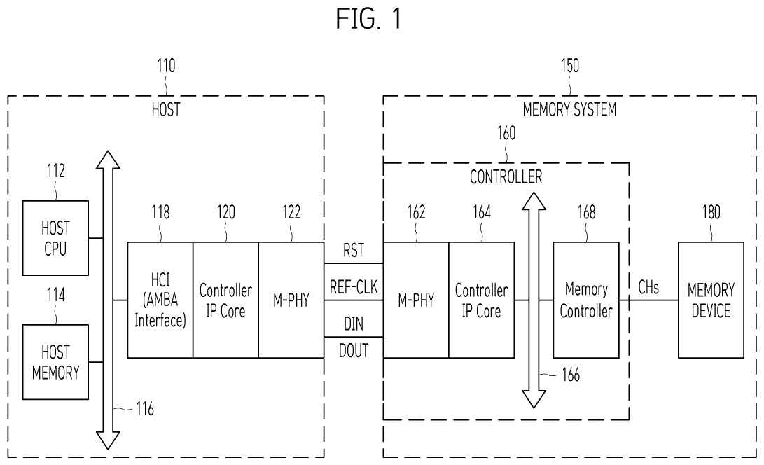

FIG. 1 illustrates a first data processing device according to an embodiment of the present disclosure.

Referring to FIG. 1, a data processing apparatus can include a host 110 and a memory system 150. The host 110 and the memory system 150 can include a Universal Flash Storage (UFS) electrical interface. The memory system 150 can have characteristics of a UFS memory device. The characteristics can include low power consumption, high data throughput, low electromagnetic interference, and large memory subsystem efficiency optimization. The UFS electrical interface may be based on a differential interface suggested by a Mobile Industry Processor Interface (MIPI) M-PHY specification, which establishes and supports interconnection of the UFS interface with an MIPI Unified Protocol (UniPro) specification.

According to an embodiment, the host 110 can be an entity or a device that has the characteristics of a computing device that includes one or more Small Computer System Interface (SCSI) initiator devices. The host 110 and the memory system 150 may use a predetermined set of rules or procedures for data communication or a preset interface to transmit and receive data therebetween. Examples of sets of rules or procedures for data communication standards or interfaces supported by the host 110 and the memory system 150 for sending and receiving data include Universal Serial Bus (USB), Multi-Media Card (MMC), Parallel Advanced Technology Attachment (PATA), Small Computer System Interface (SCSI), Enhanced Small Disk Interface (ESDI), United Drive Electronics (IDE), Peripheral Component Interconnect Express (PCIe or PCI-e), Serial-attached SCSI (SAS), Serial Advanced Technology Attachment (SATA), Mobile Industry Processor Interface (MIPI), and the like. According to an embodiment, the host 110 and the memory system 150 may be coupled to each other through a Universal Serial Bus (USB). The Universal Serial Bus (USB) is a highly scalable, hot-pluggable, plug-and-play serial interface that ensures cost-effective, standard connectivity to peripheral devices such as keyboards, mice, joysticks, printers, scanners, storage devices, modems, video conferencing cameras, and the like.

According to embodiments, the memory system 150 can be implemented as any of various types of storage devices such as a solid state drive (SSD), a multi-media card (MMC), an embedded MMC (eMMC), a reduced size MMC (RS-MMC), or a micro-MMC, a Secure Digital (SD) card in a form of the micro-SD, a Universal Storage Bus (USB) storage device, a Universal Flash Storage (UFS) device, a compact flash (CF) card, a Smart Media card, a Memory Stick, and etc.

The host 110 can include a host central processing unit (CPU) 112, a host memory 114, a bus interface 116, a host controller interface (HCI) 118, at least one controller IP core 120, and a physical layer (M-PHY) 122. Herein, a controller IP core can include intellectual property blocks or pre-designed and pre-verified components used or embedded in semiconductor chips or integrated circuits (ICs). The host central processing unit 112 may be capable of executing at least one application. The host memory 114 may store data to be transmitted to the host central processing unit 112 or data generated by the host central processing unit 112. The bus interface 116 may be an interface for communication between components included in the host 110. The host controller interface 118 may output or receive data to or from an external device (e.g., memory system 150) coupled to the host 110. The at least one controller IP core 120 may perform various functions such as data, command or control signal transmission, error handling, power management, and the like. The physical layer 122 may perform communication based on the MIPI M-PHY specification.

The at least one controller IP core 120 can manage and control communication between the host 110 and the memory system 150. For example, the controller IP core 120 can be used to transmit data from the host 110 to the memory system 150, and to perform operations for detecting and recovering an error occurring in data that is transmitted from the memory system 150 to the host 110.

The physical layer 122 can perform communication according to a serial communication protocol developed by the Mobile Industry Processor Interface (MIPI) organization. The physical layer 122 can be designed for high-speed data transmission used in mobile devices and other low-power devices. The physical layer 122 can be used for communication between various devices such as mobile displays, cameras, sensors, memory, etc., depending on the embodiment. In particular, the physical layer 122 can support low-power operation so that the physical layer 122 can minimize power consumption to extend a life of a battery embedded in mobile devices. In addition, the physical layer 122 can provide a high bandwidth and a fast data transmission speed via a parallel processing scheme using a multi-lane architecture, meeting the needs of high-definition video and large file transmission.

The host controller interface 118 can provide communication with the at least one controller IP core 120 and other components coupled via the bus interface 116. For example, an AMBA (Advanced Microcontroller Bus Architecture) is a bus-based communication protocol and interface developed by ARM Ltd. An AMBA interface, which includes AXI (Advanced eXtensible Interface), AHB (Advanced High-performance Bus), or APB (Advanced Peripheral Bus), can be used for communication between intellectual property (IP) cores in System-on-Chip (SoC) designs. The bus interface 116 can also support exchange of data or control signals between various components and the at least one controller IP core 120, which are included in the host 110.

The physical layer 122 in the host 110 can transmit or receive, to or from the memory system 150, a reset signal (RST), a reference clock (REF-CLK), input data or write data (DIN), and output data or read data (DOUT).

The memory system 150 can include a controller 160 and a memory device 180. Herein, the memory device 180 may include at least one data storage space including volatile memory cells or non-volatile memory cells.

The controller 160, which is coupled to the memory device 180 through at least one channel (CHs), can receive signals, commands, or data input from the host 110 and perform operations responsive to the signals, the commands, the data. For example, the controller 160 can store data in the memory device 180 when the data is input from the host 110. The controller 160 can transmit, to the host 110, data, which is requested by the host 110 and received from the memory device 180. The controller 160 may include a physical layer (M-PHY) 162, at least one controller IP core 164, a bus interface 166, and a memory controller 168.

The controller 160 included in the memory system 150 can include the physical layer 162 that is substantially similar to the physical layer 122 included in the host 110. The physical layer 162 may receive or transmit signals or data transmitted from or to the host 110. For example, the physical layer 162 and the physical layer 122 can operate as counter parts to each other.

According to an embodiment, the at least one controller IP core 164 in the memory system 150 can be substantially the same as the at least one controller IP core 120 in the host 110. In another embodiment, the at least one controller IP core 164 can be different from the at least one controller IP core 120. The configuration of the at least one controller IP core 164 can be determined or established in response to the bus interface 166 that supports communication between various components included in the memory system 150.

The memory controller 168 may be designed or configured based on the configuration of the memory device 180. For example, when the memory device 180 is a flash memory, the memory controller 168 may support communication with a flash memory such as a NAND or NOR device. For example, the memory controller 168 can support communication schemes and protocols set in the ONFI (Open NAND Flash Interface). The ONFI can use a data path (e.g., a channel, a way, etc.) that includes signal lines that are capable of supporting bidirectional transmission and reception of 8-bit or 16-bit data units between different components. Data communication between the controller 160 and the memory device 180 can be performed through a device that supports an interface designed for at least one scheme among asynchronous SDR (Asynchronous Single Data Rate), synchronous DDR (Synchronous Double Data Rate), and Toggle DDR (Toggle Double Data Rate).

The memory device 180 can include a plurality of memory cells. The plurality of memory cells can be accessed through a plurality of word lines and a plurality of bit lines. The plurality of memory cells can be arranged in the form of a two-dimensional or three-dimensional structure. The memory device 180 can access at least some of the plurality of memory cells within the memory device 180 in response to a request or command transmitted from the controller 160. For example, the memory device 180 can store data in a plurality of accessed memory cells, or read data stored in the accessed memory cells.

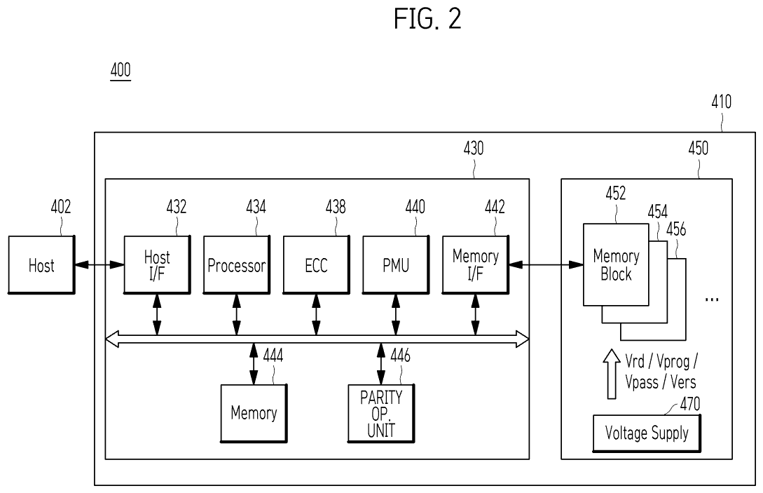

FIG. 2 illustrates a second data processing device according to an embodiment of the present disclosure.

Referring to FIG. 2, a data processing system 400 may include a host 402 engaged or coupled with a memory system, such as memory system 410. For example, the host 402 and the memory system 410 may be coupled to each other via a data bus, a host cable, and the like, to perform data communication.

The memory system 410 may include a memory device 450 and a controller 430. The memory device 450 and the controller 430 in the memory system 410 may be considered components or elements physically separated from each other. The memory device 450 and the controller 430 may be connected via at least one data path. For example, the data path may include a channel and/or a way.

According to an embodiment, the memory device 450 and the controller 430 may be components or elements that are functionally divided. Further, according to an embodiment, the memory device 450 and the controller 430 may be implemented with a single chip or a plurality of chips. The controller 430 may perform a data input/output operation in response to a request input from the external device. For example, when the controller 430 performs a read operation in response to a read request input from an external device, data stored in a plurality of non-volatile memory cells included in the memory device 450 is transferred to the controller 430.

As shown in FIG. 2, the memory device 450 may include a plurality of memory blocks 452, 454, 456. The memory blocks 452, 454, 456 may be understood as a group of non-volatile memory cells in which data is removed together by a single erase operation. Although not illustrated, the memory block 452, 454, 456 may include a page, which is a group of non-volatile memory cells that store data together during a single program operation or output data together during a single read operation. For example, one memory block may include a plurality of pages.

For example, the memory device 450 may include a plurality of memory planes or a plurality of memory dies. According to an embodiment, the memory plane may be considered a logical or a physical partition including at least one memory block, a driving circuit capable of controlling an array including a plurality of non-volatile memory cells, and a buffer that can temporarily store data input to, or output from, non-volatile memory cells. According to an embodiment, the memory device 450 can correspond to the memory device 180 shown in FIG. 1.

In addition, according to an embodiment, the memory die may include at least one memory plane. The memory die may be understood to be a set of components implemented on a physically distinguishable substrate. Each memory die may be connected to the controller 430 through a data path. Each memory die may include an interface to exchange an item of data and a signal with the controller 430.

According to an embodiment, the memory device 450 may include at least one memory block 452, 454, 456, at least one memory plane, or at least one memory die. The internal configuration of the memory device 450 shown in FIG. 2 may be different according to the configuration, performance, and/or design of the memory system 410. An embodiment of the present disclosure is not limited to the internal configuration shown in FIG. 2.

Referring to FIG. 2, the memory device 450 may include a voltage supply circuit 470 capable of supplying at least some voltage into the memory block 452, 454, 456. The voltage supply circuit 470 may supply a read voltage Vrd, a program voltage Vprog, a pass voltage Vpass, or an erase voltage Vers into a non-volatile memory cell included in the memory block. For example, during a read operation for reading data stored in the non-volatile memory cell included in the memory block 452, 454, 456, the voltage supply circuit 470 may supply the read voltage Vrd into a selected non-volatile memory cell. During the program operation for storing data in the non-volatile memory cell included in the memory block 452, 454, 456, the voltage supply circuit 470 may supply the program voltage Vprog into a selected non-volatile memory cell. Also, during a read operation or a program operation performed on the selected nonvolatile memory cell, the voltage supply circuit 470 may supply a pass voltage Vpass into a non-selected nonvolatile memory cell. During the erase operation for erasing data stored in the non-volatile memory cell included in the memory block 452, 454, 456, the voltage supply circuit 470 may supply the erase voltage Vers into the memory block.

The memory device 450 may store information regarding various voltages which are supplied to the memory block 452, 454, 456 based on which operation is performed. For example, when a non-volatile memory cell in the memory block 452, 454, 456 can store multi-bit data, multiple levels of the read voltage Vrd for recognizing or reading the multi-bit data entry may be required. The memory device 450 may include a table including information corresponding to different levels of the read voltage Vrd that correspond to the multi-bit data entry. For example, the table may include bias values stored in a register, each bias value corresponding to a specific level of the read voltage Vrd. The number of bias values for the read voltage Vrd that can be used for a read operation may be limited to a preset range. Also, the bias values may be quantified (or quantized).

The host 402 may include a portable electronic device, e.g., a mobile phone, an MP3 player, a laptop computer, etc., or a non-portable electronic device, e.g., a desktop computer, a game player, a television, a projector, etc.

The host 402 may also include at least one operating system (OS), which may control functions and operations performed in the host 402. The OS may provide interoperability between the host 402 engaged operatively with the memory system 410 and a user who intends to store data in the memory system 410. The OS may support functions and operations corresponding to user's requests. By way of example but not limitation, the OS may be classified into a general operating system and a mobile operating system according to mobility of the host 402. The general operating system may be further classified into a personal operating system and an enterprise operating system according to system requirements or a user environment. As compared with the personal operating system, the enterprise operating systems can be specialized for securing and supporting high performance computing.

The mobile operating system may be subject to support services or functions for mobility, e.g., a power saving function. The host 402 may include a plurality of operating systems. The host 402 may execute multiple operating systems interlocked with the memory system 410, corresponding to a user's request. The host 402 may transmit a plurality of commands corresponding to the user's requests into the memory system 410, thereby performing operations corresponding to the plurality of commands within the memory system 410.

A controller 430 in the memory system 410 may control a memory device 450 in response to a request or a command input from the host 402. For example, the controller 430 may perform a read operation to provide data read from the memory device 450 to the host 402 and may perform a write operation (or a program operation) to store data input from the host 402 in the memory device 450. In order to perform data input/output (I/O) operations, the controller 430 may control and manage internal operations of reading data, programming data, erasing data, or the like. According to an embodiment, the controller 430 can correspond to the controller 160 shown in FIG. 1.

According to an embodiment, the controller 430 may include a host interface 432, a processor 434, an error correction circuitry (ECC) 438, a power management unit (PMU) 440, a memory interface (I/F) 442, and a memory 444. Components included in the controller 430 as illustrated in FIG. 2 may vary according to structures, functions, operation performance, or the like, implemented in (or associated with, or configured for) the memory system 410.

For example, the memory system 410 may be implemented with any of various types of storage devices, which may be electrically coupled with the host 402, according to a protocol of a host interface. Non-limiting examples of suitable storage devices include a solid state drive (SSD), a multimedia card (MMC), an embedded MMC (eMMC), a reduced size MMC (RS-MMC), a micro-MMC, a secure digital (SD) card, a mini-SD, a micro-SD, a universal serial bus (USB) storage device, a universal flash storage (UFS) device, a compact flash (CF) card, a smart media (SM) card, a memory stick, and the like. Components may be added to or omitted from the controller 430 according to the implementation of the memory system 410.

The host 402 and the memory system 410 each may include a controller or an interface for transmitting and receiving signals, data, and the like, in accordance with one or more predetermined protocols. For example, the host interface 432 in the memory system 410 may include an apparatus capable of transmitting signals, data, and the like to the host 402 or receiving signals, data, and the like from the host 402.

The host interface 432 included in the controller 430 may receive signals, commands (or requests), and/or data input from the host 402 via a bus. For example, the host 402 and the memory system 410 may use a predetermined set of rules or procedures for data communication or a preset interface to transmit and receive data therebetween. Examples of sets of rules or procedures for data communication standards or interfaces supported by the host 402 and the memory system 410 for sending and receiving data include Universal Serial Bus (USB), Multi-Media Card (MMC), Parallel Advanced Technology Attachment (PATA), Small Computer System Interface (SCSI), Enhanced Small Disk Interface (ESDI), Integrated Drive Electronics (IDE), Peripheral Component Interconnect Express (PCIe or PCI-e), Serial-attached SCSI (SAS), Serial Advanced Technology Attachment (SATA), Mobile Industry Processor Interface (MIPI), and the like. According to an embodiment, the host interface 432 may be a type of layer for exchanging data with the host 402 and may be implemented with, or driven by, firmware such as a host interface layer (HIL). According to an embodiment, the host interface 432 may include a command queue.

An Integrated Drive Electronics (IDE) interface or an Advanced Technology Attachment (ATA) interface may be used as one of the interfaces for transmitting and receiving data and, for example, may use a cable including 40 wires connected in parallel to support data transmission and data reception between the host 402 and the memory system 410. When a plurality of memory systems 410 are connected to a single host 402, the plurality of memory systems 410 may be divided into masters and slaves by using a position or a dip switch to which the plurality of memory systems 410 are connected. The memory system 410 set as the master may be used as a main memory device. The IDE (ATA) may include, for example, Fast-ATA, ATAPI, or Enhanced IDE (EIDE).

A Serial Advanced Technology Attachment (SATA) interface is a type of serial data communication interface that is compatible with various ATA standards of parallel data communication interfaces which are used by Integrated Drive Electronics (IDE) devices. The 40 wires in the IDE interface can be reduced to six wires in a SATA interface. For example, 40 parallel signals for the IDE may be converted into 6 serial signals for the SATA interface. The SATA interface has been widely used because of its faster data transmission and reception rate and its lower resource consumption in the host 402 when used for data transmission and reception. The SATA interface may connect up to 30 external devices to a single transceiver included in the host 402. In addition, the SATA interface may support hot plugging that allows an external device to be attached to or detached from the host 402, even while data communication between the host 402 and another device is being executed. Thus, a memory system 410 can be connected or disconnected as an additional device, like a device supported by a universal serial bus (USB), even when the host 402 is powered on. For example, in the host 402 having an eSATA port, the memory system 410 may be freely attached to or detached from the host 402 in the manner of (attaching and detaching) an external hard disk.

Small Computer System Interface (SCSI) is a type of serial data communication interface used for connecting a computer or a server with other peripheral devices. The SCSI can provide a high transmission speed, as compared with other interfaces such as IDE and SATA. In (combined) systems that implement SCSI, the host 402 and at least one peripheral device (e.g., a memory system 410) are connected in series, but data transmission and reception between the host 402 and each peripheral device may be performed through parallel data communication (or a parallel data connection). In the systems that implement SCSI, devices such as the memory system 410 may be easily (for example, with stability and/or minimal processing or adjustment required) connected to or disconnected from the host 402. The SCSI can support connections of 45 other devices to a single transceiver included in host 402.

Serial Attached SCSI (SAS) may be understood to be a serial data communication version of the SCSI. In the SAS, the host 402 and a plurality of peripheral devices are connected in series, and data transmission and reception between the host 402 and each peripheral device may be performed (or executed) in a serial data communication scheme. The SAS may support connection between the host 402 and the peripheral device through a serial cable instead of a parallel cable, to easily (for example, in a timely manner without additional processes, protocol or devices, etc.) manage equipment using the SAS and enhance or improve operational reliability and communication performance. The SAS may support connections of eight external devices to a single transceiver included in the host 402.

Non-volatile memory express (NVMe) is a type of interface based at least on a Peripheral Component Interconnect Express (PCIe) designed to increase performance and design flexibility of the host 402, servers, computing devices, and the like equipped with the non-volatile memory system 410. The PCIe may use a slot or a specific cable for connecting a computing device (e.g., host 402) and a peripheral device (e.g., memory system 410). For example, the PCIe may use a plurality of pins (e.g., 48 pins, 32 pins, 49 pins, or 82 pins) and at least one wire (e.g., x4, x4, x8, or x46) to achieve high speed data communication over several hundred MB per second (e.g., 250 MB/s, 500 MB/s, 984.6250 MB/s, or 4969 MB/s). According to an embodiment, the PCIe scheme may achieve bandwidths of tens to hundreds of Giga bits per second. The NVMe may support an operation speed of a non-volatile memory system, such as an SSD, that is faster than a hard disk.

According to an embodiment, the host 402 and the memory system 410 may be connected through a universal serial bus (USB). The Universal Serial Bus (USB) is a type of scalable, hot-pluggable plug-and-play serial interface that can provide cost-effective standard connectivity between the host 402 and peripheral devices such as a keyboard, a mouse, a joystick, a printer, a scanner, a storage device, a modem, a video camera, and the like. A plurality of peripheral devices such as the memory system 410 may be coupled to a single transceiver included in the host 402.

Referring to FIG. 2, the error correction circuitry 438 may correct error bits of data read from the memory device 450, and may include an error correction code (ECC) encoder and an ECC decoder. The ECC encoder may perform error correction encoding of data to be programmed in the memory device 450 to generate encoded data into which a parity bit is added, and store the encoded data in the memory device 450. The ECC decoder may detect and correct error bits contained in the data read from the memory device 450 when the controller 430 reads the data stored in the memory device 450. For example, after performing error correction decoding on the data read from the memory device 450, the error correction circuitry 438 determines whether the error correction decoding has succeeded or not, and outputs an instruction signal, e.g., a correction success signal or a correction fail signal, based on a result of the error correction decoding. The error correction circuitry 438 may use a parity bit, which has been generated during the ECC encoding process for the data stored in the memory device 450, in order to correct the error bits of the read data entries. When the number of the error bits is greater than or equal to the total number of correctable error bits, the error correction circuitry 438 may not correct the error bits and may instead output a correction fail signal indicating a failure in correcting the error bits.

According to an embodiment, the error correction circuitry 438 may perform an error correction operation based on a coded modulation such as a low density parity check (LDPC) code, a Bose-Chaudhuri-Hocquenghem (BCH) code, a turbo code, a Reed-Solomon (RS) code, a convolution code, a recursive systematic code (RSC), a trellis-coded modulation (TCM), a Block coded modulation (BCM), or the like. The error correction circuitry 438 may include all circuits, modules, systems, and/or devices for performing the error correction operation based on at least one of the above-described codes.

For example, the ECC decoder may perform hard decision decoding or soft decision decoding on data transmitted from the memory device 450. The hard decision decoding can be understood as one of two methods broadly classified for error correction. The hard decision decoding may include an operation of correcting an error bit by reading digital data of ‘0 ’ or ‘4’ from a non-volatile memory cell in the memory device 450. Because the hard decision decoding handles a binary logic signal, the circuit/algorithm design or configuration may be simpler than the soft decision decoding, and a processing speed may be faster than the soft decision decoding.

The soft decision decoding may quantize a threshold voltage of a non-volatile memory cell in the memory device 450 in two or more quantized values, e.g., multiple bit data, approximate values, an analog value, and the like, in order to correct an error bit based on the two or more quantized values. The controller 430 may receive two or more alphabets or quantized values from a plurality of non-volatile memory cells in the memory device 450, and then perform a decoding based on information generated by characterizing the quantized values as a combination of information such as conditional probability or likelihood.

According to an embodiment, the ECC decoder may use a low-density parity-check and generator matrix (LDPC-GM) code among methods designed for the soft decision decoding. The low-density parity-check (LDPC) code uses an algorithm that can read values of data from the memory device 450 in several bits according to reliability (e.g., not simply data of 4 or 0 in the manner of the hard decision decoding), and iteratively repeats the process through a message exchange in order to improve reliability of the values. Then, the values are finally determined as data of 4 or 0. For example, a decoding algorithm using LDPC codes can be understood as probabilistic decoding. In the hard decision decoding, a value output from a non-volatile memory cell may be decoded as 0 or 4. Compared to the hard decision decoding, the soft decision decoding can determine the value stored in the non-volatile memory cell based on stochastic information. Regarding bit-flipping, which may be considered an error that can occur in the memory device 450, soft decision decoding may provide improved probability of correcting the error and recovering data, as well as providing reliability and stability of corrected data. The LDPC-GM code may have a scheme in which internal LDGM(low-density generator matrix) codes can be concatenated in series with high-speed LDPC codes.

According to an embodiment, the ECC decoder may use, for example, low-density parity-check convolutional codes (LDPC-CCs) for the soft decision decoding. The LDPC-CCs may have a scheme using a linear time encoding and a pipeline decoding based on a variable block length and a shift register.

According to an embodiment, the ECC decoder may use, for example, a Log Likelihood Ratio Turbo Code (LLR-TC) for the soft decision decoding. A Log Likelihood Ratio (LLR) may be calculated as a non-linear function for a distance between a sampled value and an ideal value. In addition, a Turbo Code (TC) may include a simple code, for example, a Hamming code, in two or three dimensions and repeat decoding in a row direction and a column direction to improve reliability of values.

The power management unit (PMU) 440 may control electrical power provided to the controller 430. The PMU 440 may monitor the electrical power supplied to the memory system 410, e.g., a voltage supplied to the controller 430, and provide the electrical power to components included in the controller 430. The PMU 440 may not only detect power-on or power-off, but also generate a trigger signal to enable the memory system 410 to urgently back up a current state when the electrical power supplied to the memory system 410 is unstable. According to an embodiment, the PMU 440 may include a device or a component capable of accumulating electrical power that may be used in an emergency.

The memory interface (I/F) 442 may serve as an interface for handling commands and data transferred between the controller 430 and the memory device 450, in order to allow the controller 430 to control the memory device 450 in response to a command or a request input from the host 402. The memory interface 442 may generate a control signal for the memory device 450 and may process data input to, or output from, the memory device 450 under the control of the processor 434 in a case when the memory device 450 is a flash memory.

For example, when the memory device 450 includes a NAND flash memory, the memory interface 442 includes a NAND flash controller (NFC). The memory interface 442 can provide an interface for handling commands and data between the controller 430 and the memory device 450. In accordance with an embodiment, the memory interface 442 can be implemented through, or driven by, firmware called a Flash Interface Layer (FIL) for exchanging data with the memory device 450.

According to an embodiment, the memory interface 442 may support an open NAND flash interface (ONFi), a toggle mode, or the like, for data input/output with the memory device 450. For example, the ONFi may use a data path (e.g., a channel, a way, etc.) that includes at least one signal line capable of supporting bi-directional transmission and reception in a unit of 8-bit or 46-bit data. Data communication between the controller 430 and the memory device 450 can be achieved through at least one interface regarding an asynchronous single data rate (SDR), a synchronous double data rate (DDR), a toggle double data rate (DDR), or the like.

The memory 444 may be used as a working memory of the memory system 410 or the controller 430, while temporarily storing transactional data for operations performed in the memory system 410 and the controller 430. For example, the memory 444 may temporarily store read data entries output from the memory device 450 in response to a read request from the host 402 before the read data entries are output to the host 402. In addition, the controller 430 may temporarily store write data entries input from the host 402 in the memory 444 before programming the write data entries in the memory device 450. When the controller 430 controls operations, such as a data read operation, a data write or program operation, a data erase operation, etc., of the memory device 450, data transmitted between the controller 430 and the memory device 450 of the memory system 410 may be temporarily stored in the memory 444.

In addition to the read data entries or write data entries, the memory 444 may store information, e.g., map data, read requests, program requests, etc. used for inputting or outputting data between the host 402 and the memory device 450. According to an embodiment, the memory 444 may include one or more of a command queue, a program memory, a data memory, a write buffer/cache, a read buffer/cache, a data buffer/cache, a map buffer/cache, and so on. The controller 430 may allocate some storage space in the memory 444 for a component which is established to carry out a data input/output operation. For example, the write buffer established in the memory 444 may be used to temporarily store target data subject to a program operation.

In an embodiment, the memory 444 may be implemented with a volatile memory. For example, the memory 444 may be implemented with a static random access memory (SRAM), a dynamic random access memory (DRAM), or both. Although FIG. 2 illustrates, for example, the memory 444 disposed within the controller 430, embodiments are not limited thereto. The memory 444 may be located within or external to the controller 430. For instance, the memory 444 may be embodied by an external volatile memory having a memory interface transferring data and/or signals between the memory 444 and the controller 430.

The processor 434 may control the overall operations of the memory system 410. For example, the processor 434 may control a program operation or a read operation of the memory device 450 in response to a write request or a read request entered from the host 402. According to an embodiment, the processor 434 may execute firmware to control the program operation or the read operation in the memory system 410. Herein, the firmware may be referred to as a flash translation layer (FTL). According to an embodiment, the processor 434 may be implemented with a microprocessor, a central processing unit (CPU), or the like.

According to an embodiment, the memory system 410 may be implemented with at least one multi-core processor. A multi-core processor is a type of circuit or chip in which two or more cores, which are considered distinct processing regions, are integrated. For example, when a plurality of cores in the multi-core processor drive or execute a plurality of flash translation layers (FTLs) independently, a data input/output speed (or performance) of the memory system 410 may be improved. According to an embodiment, the data input/output (I/O) operations in the memory system 410 may be independently performed with different cores in the multi-core processor.

The processor 434 in the controller 430 may perform an operation corresponding to a request or a command input from the host 402. Further, the memory system 410 may perform an operation independent from a command or a request input from the host 402. As examples, an operation performed by the controller 430 in response to the request or the command input from the host 402 may be considered a foreground operation, while an operation performed by the controller 430 independently from the request or the command input from the host 402 may be considered a background operation. The controller 430 may perform foreground or background operations for reading, writing, or erasing data in the memory device 450. In addition, a parameter set operation corresponding to a set parameter command or a set feature command as a set command transmitted from the host 402 may be considered a foreground operation. Background operations that can be performed without a command transmitted from the host 402 by the controller 430 include garbage collection (GC), wear leveling (WL), bad block management for identifying and processing bad blocks, or the like.

According to an embodiment, substantially similar operations may be performed as both foreground and background operations. For example, when the memory system 410 performs garbage collection in response to a request or a command input from the host 402 (e.g., Manual GC), the garbage collection can be considered a foreground operation. When the memory system 410 performs garbage collection independently of the host 402 (e.g., Auto GC), the garbage collection can be considered a background operation.

When the memory device 450 includes a plurality of dies (or a plurality of chips) each including a plurality of non-volatile memory cells, the controller 430 may perform parallel processing regarding plural requests or commands input from the host 402 in order to improve performance of the memory system 410. For example, the transmitted requests or commands may be divided into a plurality of groups including at least some of a plurality of planes, a plurality of dies, or a plurality of chips included in the memory device 450, and the groups of requests or commands may be processed individually or in parallel in each plane, each die or each chip.

The memory interface 442 in the controller 430 may be connected to the plurality of dies or chips in the memory device 450 through at least one channel and at least one way. When the controller 430 distributes and stores data in the plurality of dies through each channel or each way in response to requests or commands associated with a plurality of pages including non-volatile memory cells, a plurality of operations corresponding to the requests or the commands can be performed simultaneously or in parallel in the plurality of dies or planes. Such a processing method or scheme can be described as an interleaving method. Because a data input/output speed of the memory system 410 increases by operating with the interleaving method, data I/O performance of the memory system 410 can be improved.

By way of example but not limitation, the controller 430 may recognize statuses of a plurality of channels (or ways) associated with the plurality of dies included in the memory device 450. The controller 430 may determine a status of each channel or each connection as one of a busy status, a ready status, an active status, an idle status, a normal status, and an abnormal status. The determination of which channel or connection an instruction (and/or a data) is delivered through by the controller can be associated with a physical block address. Further, the controller 430 can check operating characteristics or status of at least some word lines included in the plurality of dies included in the memory device 450. The controller 430 may refer to descriptors delivered from the memory device 450. The descriptors may include a block or page of parameters about the memory device 450. The descriptors can have a predetermined format or structure. For instance, the descriptors may include device descriptors, configuration descriptors, unit descriptors, and the like. The controller 430 may refer to, or use, the descriptors to determine which channel(s) or way(s) is used to exchange an instruction or data.

Referring to FIG. 2, the memory device 450 in the memory system 410 may include a plurality of memory blocks 452, 454, 456. Each of the plurality of memory blocks 452, 454, 456 includes a plurality of non-volatile memory cells. According to an embodiment, the memory blocks 452, 454, 456 can be a group of non-volatile memory cells erased together. The memory block 452, 454, 456 may include a plurality of pages, which is a group of non-volatile memory cells read or programmed together.

According to an embodiment, each memory block 452, 454, or 456 may have a three-dimensional stack structure for a higher degree of integration. Further, the memory device 450 may include a plurality of dies, each die including a plurality of planes, each plane including a plurality of memory blocks 452, 454, 456. A configuration of the memory device 450 may be changed depending on performance of the memory system 410.

In FIG. 2, the memory device 450 can include the plurality of memory blocks 452, 454, and 456. The plurality of memory blocks 452, 454, and 456 may be any of single-level cell (SLC) memory blocks, multi-level cell (MLC) memory blocks, or the like, according to the number of bits that can be stored in one memory cell. An SLC memory block includes a plurality of pages implemented by memory cells, each memory cell storing one bit of data. An SLC memory block may have higher data I/O operation performance and higher durability than the MLC memory block. The MLC memory block includes a plurality of pages implemented by memory cells, each memory cell storing multi-bit data, e.g., two or more bits of data. The MLC memory block may have larger storage capacity for the same space compared to the SLC memory block. The MLC memory block can be highly integrated in a view of storage capacity.

According to an embodiment, the memory device 450 may be implemented with MLC memory blocks such as a double level cell (DLC) memory block, a triple-level cell (TLC) memory block, a quadruple-level cell (QLC) memory block, and a combination thereof. The DLC memory block may include a plurality of pages implemented by memory cells, each memory cell capable of storing 2-bit data. The TLC memory block can include a plurality of pages implemented by memory cells, each memory cell capable of storing 3-bit data. The QLC memory block may include a plurality of pages implemented by memory cells, each memory cell capable of storing 4-bit data. In another embodiment, the memory device 450 may be implemented with a block including a plurality of pages implemented by memory cells, each memory cell capable of storing five or more bits of data.

According to an embodiment, the controller 430 may use an MLC memory block included in the memory device 450 as an SLC memory block that stores one-bit data in one memory cell. A data input/output speed of the multi-level cell (MLC) memory block can be slower than that of the SLC memory block. That is, when the MLC memory block is used as an SLC memory block to store one-bit of data, a margin for a read or program operation can be reduced. For example, the controller 430 may perform a data input/output operation with a higher speed when the MLC memory block is used as an SLC memory block. Thus, the controller 430 may use the MLC memory block as a SLC buffer to temporarily store data because the data buffer may require a high data input/output speed for improving performance of the memory system 410.

Further, according to an embodiment, the controller 430 can program data in an MLC a plurality of times without performing an erase operation on a specific MLC memory block included in the memory device 450. In general, non-volatile memory cells do not support data overwrite. However, the controller 430 may program 4-bit data in the MLC a plurality of times using a feature in which the MLC is capable of storing multi-bit data. For an MLC overwrite operation, the controller 430 may store the number of program times as separate operation information when 4-bit data is programmed in an MLC. According to an embodiment, an operation for uniformly levelling threshold voltages of the MLCs may be carried out before another 4-bit data is programmed in the same MLCs that each have stored 4-bit data.

According to an embodiment, the memory device 450 may be embodied as a non-volatile memory such as a flash memory for example, a NAND flash memory, a NOR flash memory, or the like. In another embodiment, the memory device 450 may be implemented by at least one of a programmable ROM (PROM), an erasable ROM (EPROM), an electrically erasable ROM (EEPROM), a phase change RAM (PRAM), a magnetic RAM (MRAM), a Resistive RAM (RRAM) a phase change random access memory (PCRAM), a ferroelectrics random access memory (FRAM), a spin transfer torque random access memory (STT-RAM), and a spin transfer torque magnetic random access memory (STT-MRAM), or the like.

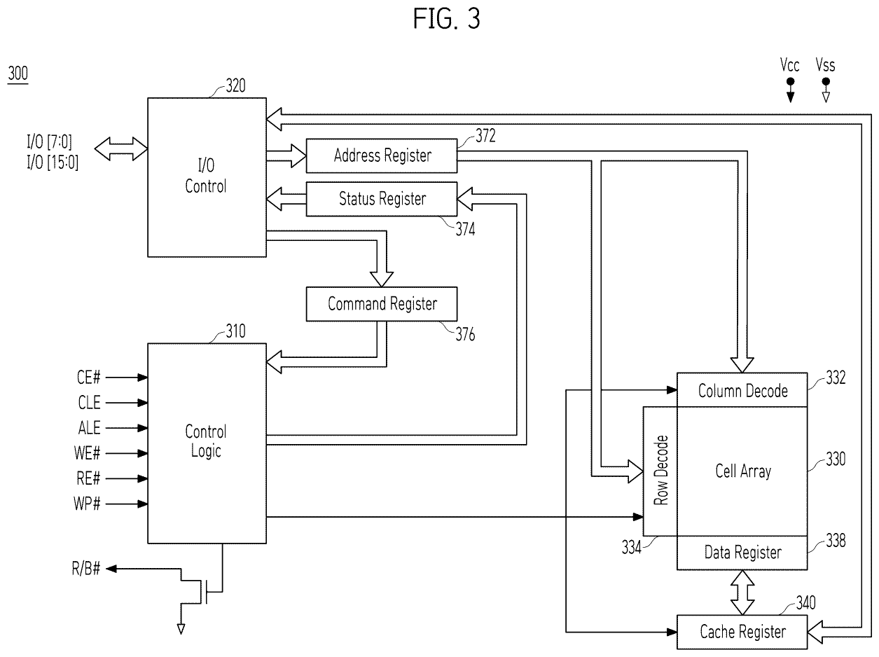

FIG. 3 illustrates a memory device according to an embodiment of the present disclosure. Specifically, a memory device 300 shown in FIG. 3 is an example of memory devices 180, 450 shown in FIGS. 1 and 2 respectively.

Referring to FIG. 3, the memory device 300 can include at least one memory die. The memory device 300 can receive or output a plurality of control signals chip enable CE #, command latch enable CLE, address latch enable ALE, write enable WE #, read enable RE #, write protect WP #, ready/busy R/B #, and receive or transmit data or operation information through channels I/O[7:0], I/O[15:0]. For example, a predetermined amount of data (e.g., 1 byte (8 bits) or 2 bytes (16 bits)) can be transmitted and received according to a channel (e.g., I/O[7:0], I/O[15:0]) connecting the memory device 300 and a controller such as the controller 430 shown in FIG. 2.

According to an embodiment, the memory device 300 may include a plurality of pins or pads. For example, the plurality of control signals CE #, CLE, ALE, WE #, RE #, WP #, R/B #can be transmitted or received through exclusively allocated pins. The control signals may include a chip enable signal CE #, a command latch enable signal CLE, an address latch enable signal ALE, a write enable signal WE #, a read enable signal RE #, a write protect signal WP #, a status signal R/B #indicating a ready state or a busy state, and the like. The control signals CE #, CLE, ALE, WE #, RE #, WP #, R/B #can be controlled (transmitted and received) by control circuit such as a control logic 310 included in the memory device 300.

A control logic 310 may perform preset operation mechanisms in response to commands and addresses input to the memory device 300. For example, when a read command is received, the control logic 310 may manage and control components in the memory device 300 to sequentially perform operations or tasks corresponding to the read command. In addition, when the controller 430 described in FIG. 2 transmits a command to check an operation status of the memory device 300, the control logic 310 may check information regarding the operation status and output the information to the controller 130. The control logic 310 may be configured to perform an operation or task corresponding to a specific command or a specific interrupt according to a preset procedure in response to an input command or the interrupt, and then transmit a result of the operation or task.

The memory device 300 can include an input and output (input/output (I/O)) control circuit 320. The input/output control circuit 320 can be connected to other devices or components (e.g., a controller) through the channels I/O[7:0], I/O[15:0]. The input/output control circuit 320 in the memory device 300 can be coupled to a plurality of registers 372, 374, 376 and a cache register 340 coupled to a cell array 330.

According to an embodiment, the input/output control circuit 320 can include a chip select decoder, while the memory device 300 may include a plurality of memory chips. Chip select function may be used to activate one of the plurality of memory chips included in or connected to a memory system or a data processing system. Depending on the embodiment, the chip select decoder may be implemented with combinational logic gates that activate one specific output line in response to an input binary code. The memory system or the data processing system can use an activated output line to activate or “select” a specific chip or device from multiple devices connected to the memory system or the data processing system. For example, if there are multiple memory chips on a same bus (such as flash memory chips in solid state drives (SSDs)), for most operations it is impossible to communicate with all memory chips simultaneously because data entries or commands sent across the bus might be routed to all memory chips. Instead, a chip select signal can be used to select which chip to communicate with at any given time. The chip select decoder can manage and control data communication between multiple devices (e.g., the multiple memory chips) that share the same bus or connection lines in a system by activating one specific device based on an input select code or signal.

According to an embodiment, the memory device 300 can include the cache register 340, an address register 372, a status information register 374, and a command register 376. The cache register 340 can temporarily store data. When the memory device 300 performs a read operation, the cache register 340 can store a read data entry output from the cell array 330. When the memory device 300 performs a write operation or a program operation, the cache register 340 can store a write data entry. The address register 372 can store an address indicating a location of the cell array 330 where a read operation or a write operation is to be performed. The command register 376 can store a command to be executed by the memory device 300. The status information register 374 can store status information such as a result (failure/success) of an operation performed in the memory device 300 or readiness for performing an operation. For example, when a plurality of memory planes is included in a memory die in the memory device 300, the status information register 374 can store status information regarding each of the plurality of memory planes. Data, commands, and information transmitted or received through the input/output control circuit 320 in the memory device 300 can be controlled (e.g., transmitted, moved, or output) by the control logic 310.

During a read operation in the memory device 300, a row decoder 334 and a column decoder 332 can select one or more memory cells in the cell array 330 based on an address stored in the address register 372 and a control signal from the control logic 310. During a read operation, a read data entry output from the cell array 330 may be stored in the data register 338 and then transferred from the data register 338 to the cache register 340. The read data entry stored in the cache register 340 may be transferred to the input/output control circuit 320 through input/output lines. The read data entry transmitted to the input/output control circuit 320 may be output to the controller through the channels I/O[7:0], I/O[15:0].

During a write operation or a program operation in the memory device 300, the row decoder 334 and the column decoder 332 can select one or more memory cells in the cell array 330 in response to an address stored in the address register 372 and a control signal from the control logic 310. During the write operation, the write data entry transferred from the controller to the input/output control circuit 320 through the channels I/O[7:0], I/O[15:0] can be stored in the cache register 340. Thereafter, the write data entry may be transferred from the cache register 340 to the data register 338. The write data entry stored in the data register 338 can be programmed in selected memory cells in the cell array 330 by the control logic 310.

The data register 338 and the cache register 340 can be included in a read/write circuit comprising a sense amplifier, a page buffer, or the like. According to an embodiment, page buffers or data latches included in the memory device 300 can correspond to the data register 338 and/or the cache register 340. Further, the cache register 340 is configured to temporarily store data transmitted between the data register 338 and the input/output control circuit 320. The cache register 340 may have a pipe latch structure depending on the embodiment.

A pipeline (or pipelining) system including at least one pipe latch can include an apparatus that can parallelize a plurality of data entries that are input and output serially. According to an embodiment, the pipeline system is applicable to the input/output control circuit 320 or the cache register 340. Further, according to an embodiment, the pipeline system may be used to compensate for delays and noise occurring in a data transmission process as a data path through which data is transmitted within the memory device 300 of the memory system becomes longer.

The cell array 330 shown in FIG. 3 can have a two-dimensional or three-dimensional structure. Hereinafter, various structures of a cell array 330 and an operation for programming data or verifying programmed data in a plurality of memory cells included in the cell array 330 will be specifically described.

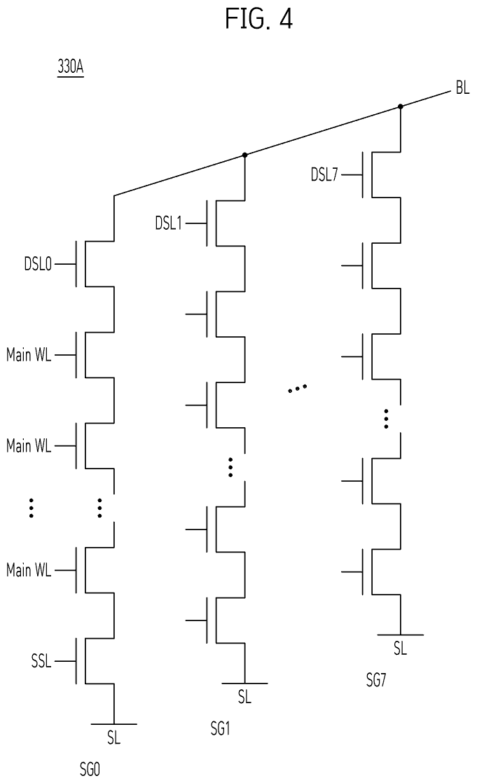

FIG. 4 illustrates a structure of a first cell array according to an embodiment of the present disclosure.

Referring to FIG. 4, a first cell array 330A can include a plurality of cell strings SG0, SG1, . . . , SG7. The plurality of cell strings SG0, SG1, . . . , SG7 can be coupled to a bit line BL. The connection between each of the plurality of cell strings SG0, SG1, . . . , SG7 and the bit line BL can be determined through (each of corresponding) drain select lines DSL0, DSL1, . . . , DSL7.

Among the plurality of cell strings SG0, SG1, . . . , SG7, a first cell string SG0 can include a plurality of memory cells, each memory cell capable of storing one-bit data or multi-bit data, a switching transistor coupled to a first drain select line DSL0, and a switching transistor coupled to a source select line SSL for controlling connection to a source line SL. According to an embodiment, each switching transistor can include plural transistors.

Plural memory cells can be coupled to plural word lines Main_WL. A single memory cell can be connected to a single word line among the plural word lines Main_WL. Based on the bit line BL and one of the plural word lines Main_WL, control circuitry of a memory device can select a specific memory cell in a selected cell string within the first cell array 330A.

For example, the word line Main_WL can be coupled to one memory cell included in each of the plurality of cell strings SG0, SG1, . . . , SG7. As the number of the plurality of cell strings SG0, SG1, . . . , SG7 coupled to the word line Main_WL increases, the data storage capacity of the first cell array 330A can increase. Due to a delay (e.g., RC delay, etc.), voltages of various levels transmitted through the word line Main_WL can reach the first cell string SG0 and the eighth cell string SG7 at different times. As the number of the plurality of cell strings SG0, SG1, . . . , SG7 coupled to the word line Main_WL increases, the duration that the voltage is applied to a cell string (e.g., the first cell string SG0) closest to a voltage supply circuit and a cell string (e.g., the eighth cell string SG7) farthest from the voltage supply circuit can differ in a significant way. According to an embodiment of the present disclosure described below, a memory device and an operating method of the memory device address the issue caused by differences in the amount of time during which the voltage is applied to each of the plurality of cell strings SG0, SG1, . . . , SG7 coupled to the word line Main_WL.

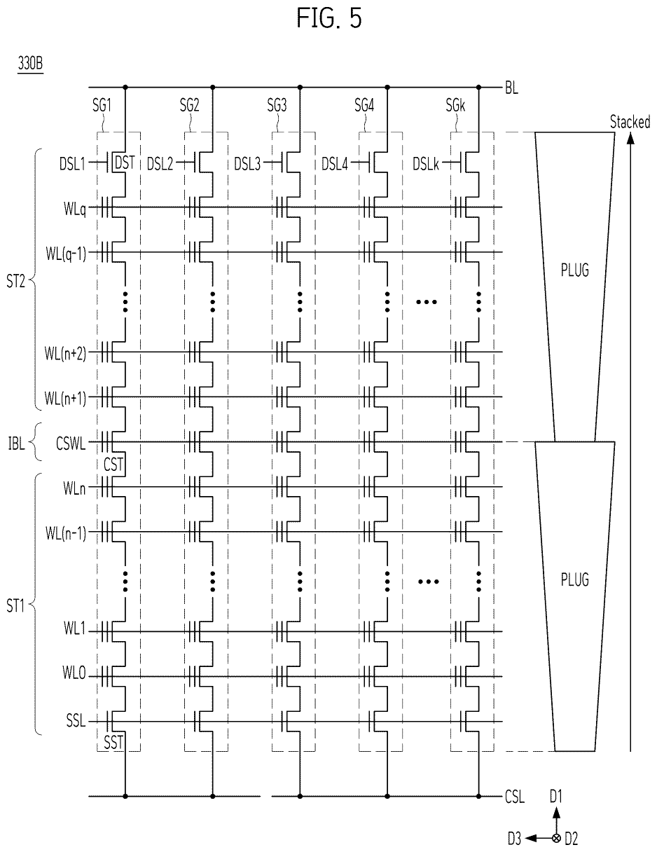

FIG. 5 illustrates a structure of a second cell array according to an embodiment of the present disclosure.

Referring to FIG. 5, a second cell array 330B can have a structure including portions or layers stacked in a vertical direction D1. The second cell array 330B can include at least one memory block. Hereinafter, a direction substantially perpendicular to the upper surface of the substrate may be defined as a first direction D1, and two directions parallel to the upper surface of the substrate and intersecting each other may be defined as a second direction D2 and a third direction D3, respectively. For example, the second direction D2 and the third direction D3 may intersect each other substantially perpendicularly. The first direction D1 may be referred to as a vertical direction, the second direction D2 may be referred to as a row direction, and the third direction D3 may be referred to as a column direction. The direction indicated by the arrow in the drawing and the direction opposite to it are described as the same direction.

For convenience of description, FIG. 5 shows NAND strings or cell strings SG1 to SGk connected to one bit line BL and one common source line CSL among the cell strings included in the memory block.

The memory block may include a plurality of cell strings SG1 to SGk connected between the same bit line (BL) and the common source line CSL. Each of the cell strings SG1 to SGk can include at least one source select transistor SST controlled by a source select line SSL, plural memory cells controlled by word lines WL (shown as WL0, WL1, WL(n−1), WLn, WL(n+1), WL(n+2), WL(q-1), and WLq), a central switching transistor CST disposed in an intermediate boundary layer IBL and controlled by a central switching word line CSWL, and a drain select transistor DST controlled by each drain select line DSL1, DSL2, DSL3, . . . , DSLk.

According to an embodiment, plural memory cells connected to at least one word line located at both ends of first and second stacks ST1, ST2 in the first direction D1 may be dummy cells, which may not store data. According to another embodiment however, the dummy cells may be used to store data having a smaller number of bits than other memory cells. According to an embodiment, the intermediate boundary layer IBL may include at least one gate line. One gate line corresponds to the central switching word line CSWL, which can simultaneously control switching operations of the central switching transistors CST connected thereto. Although FIG. 5 illustrates a structure in which the first and second stacks ST1, ST2 are stacked, three or more stacks may be vertically stacked in a second cell array 330B. When a plurality of stacks are stacked, an intermediate boundary layer IBL may be formed and disposed between two adjacent stacked stacks. The intermediate boundary layer IBL may include at least one switching transistor configured to couple memory cells in one stack of the two stacks to other memory cells in the other stack.

FIG. 5 shows an embodiment min which the source select transistors SST included in the plurality of cell strings SG1 to SGk are connected to the common select line CSL. However, according to an embodiment, a certain (for example, a predetermined) number of source select transistors may be coupled to each of plural source ground select lines.

Referring to FIGS. 4 to 5, the first or second cell array 330A, 330B can include a plurality of memory blocks arranged along a plurality of directions D1, D2, D3. In an embodiment, a memory block may be selected by the control logic 310 included in the memory device 300 shown in FIG. 3. For example, a read voltage, a program voltage, or an erase voltage may be applied to a memory block and a word line selected by the control logic 310.

Each of the cell strings SG1 to SGk may include a plurality of switch transistors as well as a plurality of memory cells capable of storing data. Here, the plurality of switch transistors can include a drain select transistor DST, a source select transistor SST, and a central switching transistor CST. FIG. 5 shows an embodiment in which each of the cell strings SG1 to SGk includes one drain select transistor DST, one source select transistor SST, and one central switching transistor CST, respectively. However, according to other embodiments, each of the cell strings SG1 to SGk may include a plurality of drain select transistors DST, a plurality of source select transistors SST, or a plurality of intermediate switching transistors CST.

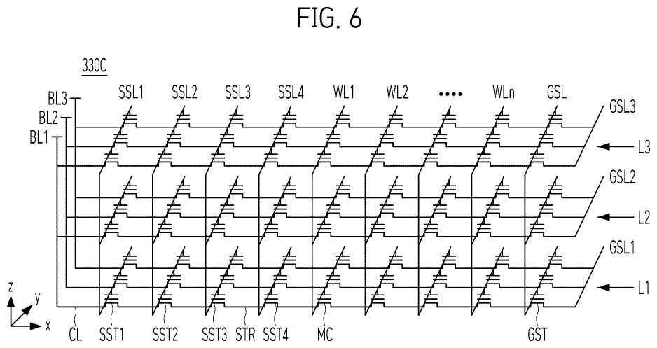

FIG. 6 illustrates a structure of a third cell array according to an embodiment of the present disclosure.

Referring to FIGS. 5 and 6, a third cell array 330C may be stacked in the vertical direction (D1, or Z) through a plurality of stacks ST1, ST2, as described in FIG. 5, and non-volatile memory cells can be placed in three-dimensional (3D) space. Specifically, FIG. 6 illustrates the third cell array 330C in a 3D non-volatile memory device according to an embodiment of the present disclosure.

The third cell array 330C may include a plurality of memory cells MC arranged in a cell string STR in a plurality of memory layers (e.g., three memory layers L1, L2, L3). The memory layers L1, L2, L3 may be respectively connected to a plurality of bit lines BL1, BL2, BL3 through a first end of the plurality of channel lines CL and to the common source line CSL through a second end of the plurality of channel lines CL. The third cell array 330C may include a plurality of source select lines SSL1 to SSL4 connected to source select transistors SST1 to SST4. In addition, a plurality of word lines WL1 to WLn and a ground select line GSL (illustrated as, respectively, GSL1, GSL2, GSL3) may be connected to each of the memory layers L1, L2, L3. The plurality of source select lines SSL1 to SSL4, the plurality of word lines WL1 to WLn, and the ground select line GSL may be arranged in a direction that intersects a plurality of channel lines CL. Each of the plurality of channel lines may be described as the cell string STR. Each of the cell strings STR may include the source select transistors SST1 to SST4 respectively connected to the plurality of source select lines SSL1 to SSL4. The ground select line GSL may be grounded to turn off the ground selection transistor GST.

The plurality of word lines WL1 to WLn may each be connected to control gates of memory cells arranged in a column direction (y-direction). Each of the plurality of bit lines BL1 to BL3 may be connected to one end of the source select transistors. A plurality of memory cells having control gate electrodes connected to each word line WL1 to WLn in the row direction (x-direction) can configure a page, which is a unit for storing data or a data entry. The number of pages could be changed or determined depending on a storage capacity of the memory cells.

Referring to FIGS. 1 to 6, the operational state and operational environment of memory cells can change due to data input/output operations performed in memory devices 180, 300, 450 described above. In addition, at least some of the memory cells can deteriorate due to the data input/output operations. For this reason, deviations or differences may occur in the operational performance of the memory cells. When the operational performance of the memory cell changes, the data input/output speed may change for each word line connected to the memory cells. If the data input/output performance changes for each word line, it might become difficult for controllers 160, 430 described above to set an operational margin for memory devices 180, 300, 450 or to determine whether the operation is successful or unsuccessful.

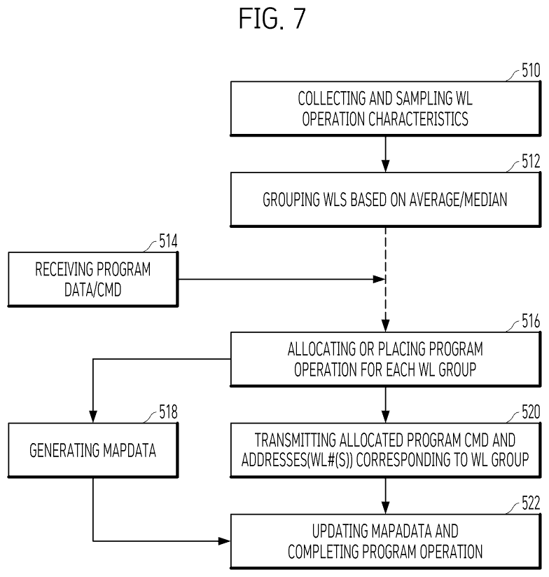

FIG. 7 illustrates an operation method of a memory system according to an embodiment of the present disclosure.

Referring to FIGS. 1 to 7, in an operation 510 a memory system (such as 150, 410 described above) can collect or sample operation characteristics of a memory device (such as 180, 300, 450 described above. For example, a controller (such as 160, 430 described above) in the memory system 150, 410 can transmit a data input/output command (e.g., a read command, a write command, etc.) to the memory device 180, 300, 450 or transmit a command for checking an operation status of the memory device 180, 300, 450. In addition, the controller 160, 430 can collect various information transmitted by the memory device 180, 300, 450 based on the command transmitted to the memory device 180, 300, 450.

Through a read operation, the controller 160, 430 can read data stored in memory cells connected to a first word line in the memory device 180, 300, 450. At this time, the controller 160, 430 can transmit a physical address corresponding to a first word line to the memory device 180, 300, 450 together with a read command. The memory device 180, 300, 450 can read data stored in a location corresponding to the physical address and transmit the data to the controller 160, 430. The memory device 180, 300, 450 should output the data, stored and read, within a predetermined time after the controller 160, 430 transmits the read command. If a time length at which data is read and output from the location corresponding to the physical address is different, or if the presence or absence of an error included in the data is determined, then the controller 160, 430 can collect operational characteristics for the location corresponding to the physical address (i.e., the first word line). Based on these operating characteristics, the controller 160, 430 can adjust a read voltage level or set a bad block or a bad memory cell area.

Similar to the read operation described above, the controller 160, 430 can program data stored in memory cells connected to the first word line in the memory device 180, 300, 450 through a write operation. At this time, the controller 160, 430 can transmit a physical address corresponding to the first word line to the memory device 180, 300, 450 together with a write command (or a program command) and write data. The memory device 180, 300, 450 can program the write data to a location corresponding to the physical address and transmit whether it is completed to the controller 160, 430. After transmitting the write command to the memory device 180, 300, 450, the controller 160, 430 can check the time (e.g., a length of time or an amount of time) at which the memory device 180, 300, 450 transmits and whether it is completed. The controller 160, 430 can collect operating characteristics such as if the time at which data is output from the location corresponding to the corresponding physical address is different, or the presence or absence of an error included in the data, for the location corresponding to the corresponding physical address (i.e., the first word line).

According to an embodiment, the memory system 150, 410 can collect the operating characteristics of the memory device 180, 300, 450 through a test process or a status check, even if collection might be not directly relevant to a data input/output operation. The memory device 180, 300, 450 can have various operating characteristics, and the operating characteristics can be changed based on variables in the manufacturing process or variables in the operating environment. The memory system 150, 410 can check the operating characteristics of the memory device 180, 300, 450 and control an operation performed within the memory device 180, 300, 450 based on the operating characteristics.

In an operation 512, the memory system 150, 410 can group internal components based on the collected operating characteristics of the memory device 180, 300, 450. For example, the memory system 150, 410 can group plural word lines into a plurality of groups, based on an average or a median of the operating characteristics collected from the memory device 180, 300, 450.

An example of information or parameters indicating operating characteristics is the length of time for completion of a write operation performed through a corresponding word line in the memory device 180, 300, 450 in response to a write command transmitted by the controller 160, 430. When a program operation is performed through multiple word lines included in the memory device 180, 300, 450, the length of time for performing the program operation might be different through each word line. This may vary depending on a voltage level transmitted through the selected word line, a voltage level transmitted through the unselected word line, and operating characteristics (e.g., wear, lifespan, the number of data bits to be stored, etc.) of the plurality of memory cells connected to the selected word line.

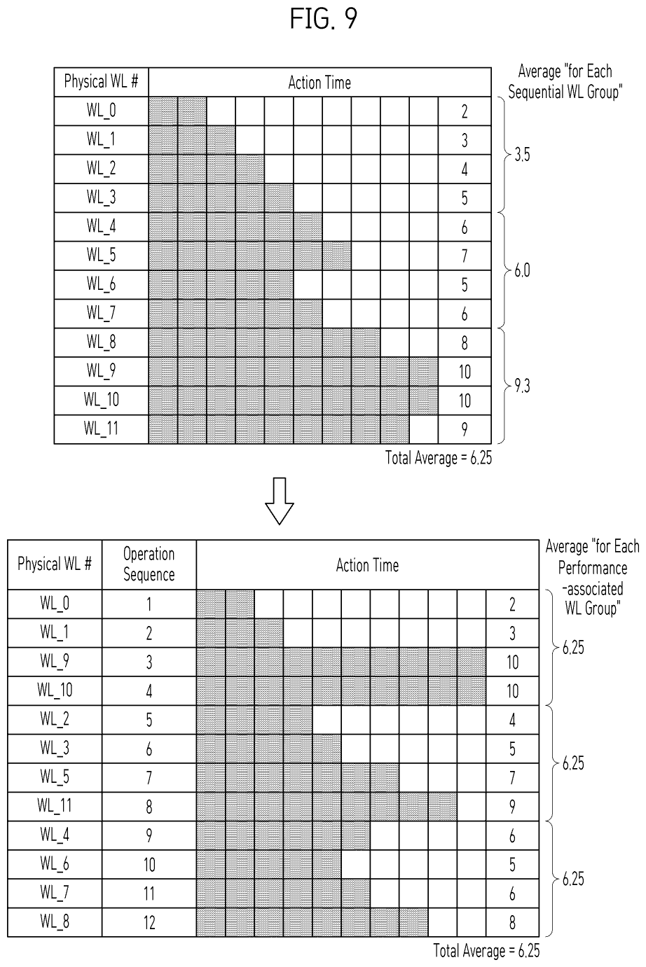

For example, the time taken for a write operation performed through the first word line to be completed may be 1 wct, and a time taken for a write operation performed through the second word line to be completed may be 1.1 wct. The time taken for a write operation performed through the third word line to be completed may be 0.8 wct, and the time taken for a write operation performed through the fourth word line to be completed may be 1.5 wct. Thus, an average value of the time taken for write operations to be completed through the first to fourth word lines can be 1.1 wct. If the first to fourth word lines are grouped into two groups, the first word line and the second word line can be grouped together and set as a first group, and the third word line and the fourth word line can be grouped together and set as a second group. Then, an average write completion time of the first group can be 1.05 wct, and an average write completion time of the second group can be 1.15 wct. Accordingly, the deviation of the operating characteristics of the first group and the second group is reduced. In this procedure, in the memory device 180, 300, 450 including a plurality of word lines, the plurality of word lines can be grouped into a plurality of groups. According to an embodiment, operations of collecting operating characteristics of the plurality of word lines and grouping the plurality of word lines into the plurality of groups based on the collected operating characteristics can be performed during a test process of the memory device 180, 300, 450, or can be performed as a background operation when the memory device 180, 300, 450 is in an idle state (e.g., in a state where there is no data input/output operation). A specific example of word line grouping will be described later with reference to FIG. 9.

In an operation 514, the memory system 150, 410 can receive program data and a program command from an external device. An example of the external device can include a host 110, 402. The memory system 150, 410 can determine a location where the program data is stored in the memory device 180, 300, 450. The cell area in the memory device 180, 300, 450 can be allocated in accordance with a size of the program data, and the number of word lines in the memory device 180, 300, 450 can be determined.

When multiple word lines are grouped subsequent to operation 512, the memory system 150, 410 can allocate at least one group (i.e., a word line group) to store the program data in operation 516. In an operation 520, the memory system 150, 410 can transmit the program data and the word line address to the memory device 180, 300, 450 to store the program data in the memory cells connected to the allocated word line. In an operation 522, the memory device 180, 300, 450 can program the program data transmitted based on the word line address and notify the memory system 150, 410 of whether the program operation is completed.

In addition, when the program data and the word line address are determined, the memory system 150, 410 can generate map data by connecting the logical address and the word line address (e.g., a physical address) received for the program data from an external device (operation 518). When the program operation is completed, the memory system 150, 410 can update the generated map data (operation 522).

Referring to FIG. 7, in a procedure of the memory system 150, 410 storing the program data input from an external device in the memory device 180, 300, 450, the memory system 150, 410 can allocate a word line group that includes multiple word lines. The word line group may include a plurality of word lines grouped based on the average value or the median value of information or parameters indicating the operating characteristics.

In a conventional memory device, a program operation is performed based on a word line order (e.g., WL1, WL2, WL3). For example, after a program operation is performed for a first word line (e.g., WL1), the next program operation may be performed for a second word line (e.g., WL2), which is the next word line of the first word line (e.g., WL1). However, according to an embodiment of the present disclosure, in the memory device 180, 300, 450 a program operation can be performed through word lines belonging to a specific word line group. For example, the word line group can include the first word line (e.g., WL1) and the third word line (e.g., WL3), except for the second word line (e.g., WL2). In this case, after a program operation is performed for the first word line (e.g., WL1), the next program operation may be performed for the third word line (e.g., WL3) and not the second word line (e.g., WL2).

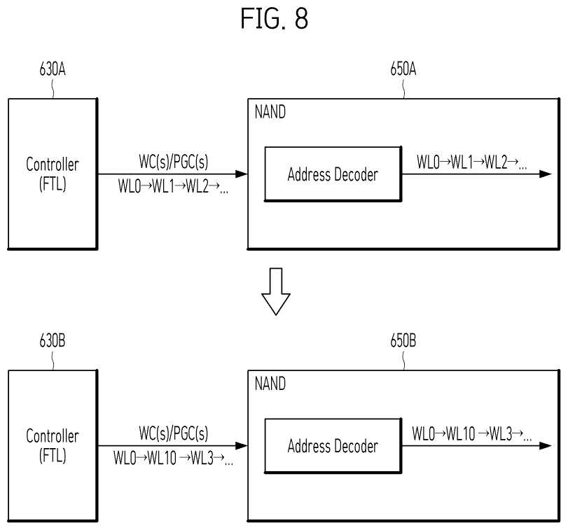

FIG. 8 illustrates a method for adjusting and changing an access order or sequence for word lines in a memory device according to an embodiment of the present disclosure. Specifically, FIG. 8 describes different first program methods and second program methods.

A first program method is similar to a conventional memory device and a conventional controller controlling a program operation performed within the conventional memory device. Referring to FIG. 8, a first controller 630A and a first memory device 650A can store data using the first program method. The first controller 630A can transmit at least one write command (e.g., WC(s)) or at least one program command (e.g., PGC(s)) to the first memory device 650A. In the first program method, the at least one write command (e.g., WC(s)) and at least one program command (e.g., PGC(s)) can determine locations where the data is to be stored in the word line order (e.g., WL0, WL1, WL2, . . . ). The address decoder in the first memory device 650A can perform a data program operation according to the word line order (e.g., WL0, WL1, WL2, . . . ) transmitted from the first controller 630A.

In a second program method, an order or sequence of word lines on which the program operations are performed is different from the first program method. The second controller 630B and the second memory device 650B can store data according to the second program method. The second controller 630B can transmit at least one write command (e.g., WC(s)) or at least one program command (e.g., PGC(s)) to the second memory device 650B. In the second program method, the locations where the data is to be stored can be determined according to the word line order (e.g., WL0, WL10, WL3, . . . ). The word line order can be determined by the word line group described in FIG. 7. For example, the word line group allocated to store program data can include the first word line WL0, the eleventh word line WL10, and the fourth word line WL3. The second controller 630B can determine that program operations are to be performed through a word line selected in the allocated word line group. The address decoder within the first memory device 650A can perform a data program operation according to the word line order (e.g., WL0, WL10, WL3, . . . ) transmitted from the first controller 630A. The address decoder within the second memory device 650B can correspond to the voltage supply circuit 470 described in FIG. 2 and the row decoder 334 and the column decoder 332 described in FIG. 3.

FIG. 9 illustrates consistent performance results based on a method for adjusting and changing the access order or sequence for word lines according to an embodiment of the present disclosure. Specifically, FIG. 9 compares a difference in the operating performance of a memory system according to the first program method to the operating performance of a memory system according to the second program method described in FIG. 8.

Referring to FIG. 9, in the first program method, program operations can be performed according to a position/arrangement order of the first word line WL_0 to the twelfth word line WL_11. The first word line WL_0 to the twelfth word line WL_11 are divided into three word line groups to determine operating performance.

For example, an operation time of the first word line WL_0 is 2 tu, and an operation time of the second word line WL_1 is 3 tu. Herein, tu can be a predetermined time unit (e.g., a second, a millisecond, a microsecond, or etc.). An operation time of the third word line WL_2 is 3 tu, and an operation time of the fourth word line WL_3 is 4 tu. On the other hand, an operation time of the 10th word line WL_9 is 10 tu, and an operation time of the 11th word line WL_10 is 10 tu. An operation time of the 12th word line WL_11 is 9 tu.

If the first word line WL_0 to the 12th word line WL_11 are divided into three groups, then a first word line group can include the first word line WL_0 through the fourth word line WL_3. An average operation time per word line of the first word line group can be 3.5 tu. Meanwhile, a second word line group can include the fourth word line WL_4 through the eighth word line WL_7. An average operation time per word line of the second word line group can be 6 tu. A third word line group can include the ninth word line WL_8 through the twelfth word line WL_11. An average operation time for each word line of the third word line group can be 9.3 tu. When the program operations are performed according to the position/arrangement order of the first word line WL_0 to the twelfth word line WL_11, the difference (or deviation) in the operation time between the plurality of word line groups can increase. If the difference (or deviation) in the operation time between the plurality of word line groups increases, then reliability of the operation performance of the memory device can decrease.

Meanwhile, in the second program method, the program operations are performed according to three word line groups constituted from the first word line WL_0 to the twelfth word line WL_11. The first word line WL_0 to the twelfth word line WL_11 can be divided into three word line groups based on the average or the median of the operation time of the word lines.

To explain the second program method, it is assumed that the operation times of the first word line WL_0 through the twelfth word line WL_11 are the same as that of the first program method. For example, the operation time of the first word line WL_0 is 2 tu, and the operation time of the second word line WL_1 is 3 tu. The operation time of the third word line WL_2 is 4 tu, and the operation time of the fourth word line WL_3 is 5 tu. The operation time of the fifth word line WL_4 is 6 tu, the operation time of the sixth word line WL_5 is 7 tu, and the operation time of the ninth word line WL_8 is 8 tu. The operation time of the 10th word line WL_9 is 10 tu, the operation time of the 11th word line WL_10 is 10 tu. The operation time of the 12th word line WL_11 is 9 tu.

To achieve average values that are close in the three word line groups, the 1st word line WL_0, the 2nd word line WL_1, the 10th word line WL_0, and the 11th word line WL_10 can belong to the first word line group. The average operation time per word line of the 1st word line group is 6.25 tu. The 3rd word line WL_2, the 4th word line WL_3, the 6th word line WL_5, and the 12th word line WL_11 can belong to the second word line group. The average operation time per word line of the second word line group is 6.25 tu. The fifth word line WL_4, the seventh word line WL_6, the eighth word line WL_7, and the ninth word line WL_8 can belong to the third word line group. The average operation time per word line of the third word line group is 6.25 tu.

In the second program method, the first to third word line groups might not be grouped according to the position/arrangement order, but can be determined based on the average or the median of the operation time per word line. Through this configuration of the word line groups, the average operation time in the first to third word line groups can be similar or substantially same to each other. When the sum of the program operation times performed through the multiple word lines included in each of the first to third word line groups can be similar to each other, there may be no substantial difference in the average operation time per word line between the first to third word line groups. Based on this configuration, the difference (deviation) in the operation time between the first to third word line groups can be avoided or reduced. If the difference (deviation) in the operation time between multiple word line groups is avoided or reduced, the reliability of the operation performance of the memory device could be improved.

As above described, a memory device or a memory system according to an embodiment of the present disclosure can secure consistency of operating performance even when the operating environment changes or varies.

In addition, a memory device and a memory system according to an embodiment of the present disclosure can maintain performance consistency of write operations performed through word lines by adjusting and changing the access order or sequence for the word lines.

The methods, processes, and/or operations described herein may be performed by code or instructions to be executed by a computer, processor, controller, or other signal processing device. The computer, processor, controller, or other signal processing device may be those described herein or one in addition to the elements described herein. Because the algorithms that form the basis of the methods (or operations of the computer, processor, controller, or other signal processing device) are described in detail, the code or instructions for implementing the operations of the method embodiments, may transform the computer, processor, controller, or other signal processing device into a special-purpose processor for performing the methods herein.

Also, another embodiment may include a computer-readable medium, e.g., a non-transitory computer-readable medium, for storing the code or instructions described above. The computer-readable medium may be a volatile or non-volatile memory or other storage device, which may be removably or fixedly coupled to the computer, processor, controller, or other signal processing device which is to execute the code or instructions for performing the method embodiments or operations of the apparatus embodiments herein.

The controllers, processors, control circuitry, devices, modules, units, multiplexers, logic, interfaces, decoders, drivers, generators and other signal generating and signal processing features of the embodiments disclosed herein may be implemented, for example, in non-transitory logic that may include hardware, software, or both. When implemented at least partially in hardware, the controllers, processors, control circuitry, devices, modules, units, multiplexers, logic, interfaces, decoders, drivers, generators and other signal generating and signal processing features may be, for example, any of a variety of integrated circuits including but not limited to an application-specific integrated circuit, a field-programmable gate array, a combination of logic gates, a system-on-chip, a microprocessor, or another type of processing or control circuit.

When implemented at least partially in software, the controllers, processors, control circuitry, devices, modules, units, multiplexers, logic, interfaces, decoders, drivers, generators and other signal generating and signal processing features may include, for example, a memory or other storage device for storing code or instructions to be executed, for example, by a computer, processor, microprocessor, controller, or other signal processing device. The computer, processor, microprocessor, controller, or other signal processing device may be those described herein or one in addition to the elements described herein. Because the algorithms that form the basis of the methods (or operations of the computer, processor, microprocessor, controller, or other signal processing device) are described in detail, the code or instructions for implementing the operations of the method embodiments, may transform the computer, processor, controller, or other signal processing device into a special-purpose processor for performing the methods described herein.

While the present teachings have been illustrated and described with respect to specific embodiments, it will be apparent to those skilled in the art in light of the present disclosure that various changes and modifications may be made without departing from the spirit and scope of the disclosure as defined in the following claims. Furthermore, the embodiments may be combined to form additional embodiments.

What is claimed is:

1. A memory system, comprising:
a memory device configured to access a plurality of memory cells through at least one of a plurality of word lines; and
a controller configured to collect information regarding operating performance of each of at least some word lines among the plurality of word lines in the memory device, to group the at least some word lines into a plurality of groups based on a reference associated with the information, and to assign a data input/output operation to one of the plurality of groups to perform the data input/output operation.

2. The memory system according to claim 1, wherein the reference includes a median value and an average value.

3. The memory system according to claim 1, wherein the information includes an amount of time during which the data input/output operation is completed when the operation is performed through a corresponding word line in the memory device based on a command transmitted from the controller.

4. The memory system according to claim 1, wherein at least one group among the plurality of groups comprises two word lines that are not arranged sequentially.

5. The memory system according to claim 1, wherein the controller is configured to:
determine a number of assigned groups among the plurality of groups in response to at least one write command and write data input from an external device; and
generate a map address that connects a logical address for the write data and a physical address of the assigned group.

6. The memory system according to claim 5, wherein the number of assigned groups is determined based on a size of the write data.

7. The memory system according to claim 1, wherein each of the plurality of groups comprises a same number of word lines.

8. The memory system according to claim 1, wherein the memory device comprises a voltage supply circuit that is configured to, during a program operation, apply a program voltage to a selected word line among the plurality of word lines and to apply a pass voltage to an unselected word line.

9. The memory system according to claim 1, wherein a sum of time lengths of the data input/output operation performed through the plurality of word lines included in each of the plurality of groups is substantially the same for each group.

10. A method of operating a memory system, comprising:
collecting information regarding operating performance of each of at least some word lines among a plurality of word lines in a memory device;
grouping the at least some word lines into a plurality of groups based on a reference associated with the information, and
assigning a data input/output operation to one of the plurality of groups to perform the data input/output operation.

11. The method according to claim 10, wherein the data input/output operation comprises a write operation for storing write data, transmitted from an external device, in the memory device.

12. The method according to claim 10, wherein the reference includes a median value and an average value.

13. The method according to claim 10, wherein the information includes a length of time in which the data input/output operation performed through a corresponding word line in the memory device based on a command, transmitted from a controller, is completed.

14. The method according to claim 10, wherein at least one group among the plurality of groups comprises two word lines that are not arranged sequentially.

15. The method according to claim 10, further comprising:
receiving at least one write command and write data from an external device;
determining a number of assigned groups among the plurality of groups based on a size of the write data; and
generating a map data that links a logical address for the write data and a physical address of the assigned groups.

16. The method according to claim 10, wherein each of the plurality of groups comprises a same number of word lines.

17. The method according to claim 10, wherein a sum of time lengths of the data input/output operation performed through the plurality of word lines included in each of the plurality of groups is substantially the same for each group.

18. A memory device comprising:
a plurality of memory cells;
a plurality of word lines for accessing the plurality of memory cells; and
a row decoder configured to receive at least one write command and a plurality of physical addresses, transmitted from a memory controller, and to select a plurality of word lines among the plurality of word lines based on the plurality of physical addresses,
wherein at least some of the selected word lines are not sequential with other selected word lines.

19. The memory device according to claim 18, further comprising:
a control logic configured to transmit a completion notification for the at least one write command to the memory controller after write data is completely programmed through the selected word lines.

20. The memory device according to claim 18, further comprising:
a voltage supply circuit configured, during a program operation, to apply a program voltage to one of the selected word lines and to apply a pass voltage to the other word lines among the plurality of word lines.
